(19) United States
(12) Patent Application Publication
(10) Pub. No.: US 2008/0251861 A1
(43) Pub. Date: Oct. 16, 2008

(54) SEMICONDUCTOR APPARATUS AND PRODUCTION METHOD OF THE SAME

(75) Inventor: Hiroaki TAKETANI, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/100,158

(22) Filed: Apr. 9, 2008

(30) Foreign Application Priority Data
Apr. 11, 2007 (JP) 2007-103495

(51) Int. Cl. H01L 29/00; H01L 21/8236

(52) U.S. Cl. 257/408; 438/278; 257/E29.001; 257/E21.631

(57) ABSTRACT

In order to provide a semiconductor apparatus and a production method of the semiconductor apparatus that achieves a small interface trap density by implantation of fluorine and that achieves both small property fluctuation and a small leak current, a semiconductor apparatus includes: a semiconductor substrate; a well layer formed on the semiconductor substrate; a channel dope layer formed on the well layer; a source/drain diffused layer provided at an upper peripheral of the channel dope layer; gate electrodes formed on the channel dope layer via a gate insulation film; a polycrystalline silicon plug which is formed between the gate electrodes and which touches the source/drain diffused layer while piercing the gate insulation film; and fluorine which is selectively implanted only in a source area of the source/drain diffused layer.

### BACKGROUND OF THE INVENTION

1. Field of the Invention

The present invention relates to a semiconductor apparatus and a production method of the semiconductor apparatus. In particular, the present invention relates to a semiconductor apparatus and a production method of the semiconductor apparatus that achieves a small interface trap density between a semiconductor and an insulation film of a MOS (metal-oxide semiconductor) apparatus and that achieves small property fluctuation and a small leak current.

Priority is claimed on Japanese Patent Application No. 2007-103495, filed Apr. 11, 2007, the content of which is incorporated herein by reference.

2. Description of the Related Art

An element area of a MOS (metal-oxide semiconductor) apparatus is formed by dividing a semiconductor substrate with an insulation film. The interface trap density is at a boundary between the semiconductor and the insulation film because of, for example, a dangling bond and lattice defect.

Such an interface trap density causes a trap with regard to a carrier. Therefore, if the interface trap density is not small enough, a generation current is caused and a leak current increases. In addition, an interface trap density of a gate insulation film causes a property fluctuation such as fluctuation in the threshold voltage of the semiconductor apparatus over time, and causes adverse effects on the quality of the semiconductor apparatus.

With regard to a memory cell of DRAM (dynamic random access memory), an increase of such a small amount of leak current and fluctuation of the threshold voltage deteriorates refresh characteristics.

There is a well-known method in a conventional technique for reducing interface trap density in that the dangling bond on silicon is terminated with hydrogen by heating the silicon in a hydrogen atmosphere in order to obtain a Si—H bond at the end of molecules.

However, the Si—H bond can easily be cut due to a heating stress by applying a high temperature, injection of hot-carrier, and the like, and consequently, a dangling bond can be generated again. Therefore, in the conventional technique, a Si—F bond that is stronger than the Si—H bond is used by introducing fluorine on an interface of silicon.

There are several types of methods for introducing fluorine, and an ion implantation method is one of the most easy and convenient methods.

For example, in Patent Document 1, a method is explained in which after forming a source-drain area, an ion implantation of fluorine on an overall surface of the substrate and a heating operation is conducted, and consequently, the dangling bond is terminated with fluorine.

In Patent Document 2, a method is explained in which fluorine is implanted on a surface of the silicon substrate around gate electrode of an area on which pMOS is formed, and after that, a lamp annealing and an operation of annealing in an oven are conducted.

In Patent Document 3, a method is explained in which an ion implantation of fluorine is conducted by using a resist mask which has been used for a patterning operation of a gate electrode, and an ion implantation of boron is conducted on an area on which pMOS is formed.
[Patent Document 1] Japanese Patent Application, First Publication No. 2000-269492
[Patent Document 2] Japanese Patent Application, First Publication No. 2001-56291
[Patent Document 3] Japanese Patent Application, First Publication No. H08-330441

However, if fluorine is implanted into a silicon substrate, many point defects are caused by this implantation. Due to a production process in a low temperature because of applying fine or narrow wirings in recent years, such point defects are not sufficiently recovered and remain in a depletion layer. Therefore, such remaining point defects cause a connection leak and property fluctuation of the semiconductor apparatus.

The present invention was conceived in order to solve the above-described problems and provides a semiconductor apparatus and a production method of the semiconductor apparatus that achieves a small interface trap density by implantation of fluorine and that achieves both small property fluctuations and a small leak current.

### SUMMARY OF THE INVENTION

In order to solve the above-described problems, the present invention provides, for example, following aspects.

A first aspect is a semiconductor apparatus which includes: a semiconductor substrate; a well layer formed on the semiconductor substrate; a channel dope layer formed on the well layer; a source/drain diffused layer provided at an upper peripheral of the channel dope layer; gate electrodes formed on the channel dope layer via a gate insulation film; a polycrystalline silicon plug which is formed between the gate electrodes and which touches the source/drain diffused layer while piercing the gate insulation film; and fluorine which is selectively implanted only in a source area of the source/drain diffused layer.

A second aspect is the above-described semiconductor apparatus, wherein the fluorine is preferably included in the source layer at a range from 1×10¹⁸/cm³ to 1×10²²/cm³.

A third aspect is the above-described semiconductor apparatus, wherein a dose amount of the fluorine is preferably in a range from 1×10¹⁴/cm² to 1×10¹⁷/cm².

A fourth aspect is the above-described semiconductor apparatus, wherein a dose amount of the fluorine is preferably in a range from 1×10¹⁵/cm² to 1×10¹⁶/cm².

A fifth aspect is the above-described semiconductor apparatus, wherein the fluorine is preferably implanted with acceleration energy of 0.5-50 keV.

A sixth aspect is the above-described semiconductor apparatus, wherein the fluorine is diffused form the source area to a silicon oxide film interface preferably by conducting a heating operation after implanting the fluorine.

A seventh aspect is a production method of a semiconductor apparatus which includes the steps of: forming a well layer on a semiconductor substrate; forming a channel dope layer on the well layer; forming a source/drain diffused layer at an upper peripheral of the channel dope layer; forming gate electrodes on the channel dope layer via a gate insulation film; forming a polycrystalline silicon plug which touches the source/drain diffused layer while piercing the gate insulation film, between the gate electrodes; and selectively implanting fluorine only in a source area of the source/drain diffused layer.

An eighth aspect is preferably the above-described production method of a semiconductor apparatus wherein, the fluorine is selectively implanted only in the source area by using a photoresist mask.

A ninth aspect is the above-described production method of a semiconductor apparatus wherein, the fluorine is preferably included in the source layer at a range from 1×10¹⁸/cm³ to 1×10²²/cm³ at the step of selectively implanting fluorine.

A tenth aspect is the above-described production method of a semiconductor apparatus wherein, a dose amount of the fluorine is preferably in a range from 1×10¹⁴/cm² to 1×10¹⁷/cm² at the step of selectively implanting fluorine.

A tenth aspect is the above-described production method of a semiconductor apparatus wherein, a dose amount of the fluorine is preferably in a range from 1×10¹⁵/cm² to 1×10¹⁶/cm² at the step of selectively implanting fluorine.

An eleventh aspect is the above-described production method of a semiconductor apparatus wherein, the fluorine is implanted with an acceleration energy of 0.5-50 keV at the step of selectively implanting fluorine.

A twelfth aspect is the above-described production method of a semiconductor apparatus further including a step of diffusing the fluorine from the source area to a silicon oxide film interface by heating at a temperature in a range from 600-1100° C. after the step of selectively implanting fluorine.

The above-described semiconductor apparatus includes: a semiconductor substrate; a well layer formed on the semiconductor substrate; a channel dope layer formed on the well layer; a source/drain diffused layer provided at an upper peripheral of the channel dope layer; gate electrodes formed on the channel dope layer via a gate insulation film; a polycrystalline silicon plug which touches the source/drain diffused layer while piercing the gate insulation film; and fluorine which is selectively implanted only in a source area of the source/drain diffused layer. Therefore, it is possible to eliminate defects due to ion implantation on the drain area. Fluorine is supplied from the source area to the silicon oxide film interface. Therefore, the dangling bond of the silicon oxide film interface is terminated, and it is possible to reduce interface trap density. Consequently, it is possible to obtain a semiconductor apparatus with a small property fluctuation and a small leak current.

In addition, in the above-described semiconductor apparatus, the fluorine is preferably included in the source layer at a range from 1×10¹⁸/cm³ to 1×10²²/cm³. Therefore, sufficient amount of fluorine is implanted in the interface, and it is possible to reduce interface trap density of a semiconductor substrate.

In the above-described semiconductor apparatus, a dose amount of the fluorine is preferably in a range from 1×10¹⁴/cm² to 1×10⁷/cm². Therefore, sufficient amount of fluorine is implanted in the interface, and it is possible to effectively reduce the interface trap density of a semiconductor substrate.

In the above-described semiconductor apparatus, the dose amount of the fluorine is preferably in a range from 1×10¹⁵/cm² to 1×10¹⁶/cm². Therefore, it is possible to further effectively reduce the interface trap density of a semiconductor substrate.

In the above-described semiconductor apparatus, the fluorine is diffused from the source area to a silicon oxide interface by conducting a heating operation after implanting the fluorine. Therefore, the dangling bond of the silicon oxide film interface is terminated, and it is possible to effectively reduce the interface trap density of the semiconductor apparatus.

The above-described production method of a semiconductor apparatus includes the steps of: forming a well layer on a semiconductor substrate; forming a channel dope layer on the well layer; forming a source/drain diffused layer at an upper peripheral of the channel dope layer; forming gate electrodes on the channel dope layer via a gate insulation film; forming a polycrystalline silicon plug which touches the source/drain diffused layer while piercing the gate insulation film, between the gate electrodes; and selectively implanting fluorine only in a source area of the source/drain diffused layer. Therefore, it is possible to eliminate defects due to ion implantation on the drain area. Fluorine is supplied from the source area to the silicon oxide film interface. Therefore, the dangling bond of the silicon oxide film interface is terminated, and it is possible to reduce interface trap density. Consequently, it is possible to reduce property fluctuation and leak current.

In the above-described production method of a semiconductor apparatus, the fluorine is selectively implanted only in the source area by using a photoresist mask. Therefore, it is possible to reduce the number of production steps of the semiconductor apparatus, and it is possible to achieve an easy operation of selectively implanting fluorine.

In the above-described production method of a semiconductor apparatus, the fluorine is included in the source layer at a range from 1×10¹⁸/cm³ to 1×10²²/cm³ at the step of selectively implanting fluorine. Therefore, it is possible to sufficiently reduce interface trap density.

In the above-described production method of a semiconductor apparatus, a dose amount of the fluorine is in a range from 1×10¹⁴/cm² to 1×10¹⁷/cm² at the step of selectively implanting fluorine. Therefore, a sufficient amount of fluorine is implanted in the interface, and it is possible to effectively reduce interface trap density of a semiconductor substrate.

In the above-described production method of a semiconductor apparatus, a dose amount of the fluorine is in a range from 1×10¹⁵/cm² to 1×10¹⁶/cm² at the step of selectively implanting fluorine. Therefore, it is possible to further effectively reduce interface trap density of a semiconductor substrate.

In the above-described production method of a semiconductor apparatus, the fluorine is implanted with an acceleration energy of 0.5-50 keV at the step of selectively implanting fluorine. Therefore, it is possible to effectively implant fluorine at a desired or preferable area until a desired or preferable depth.

The above-described production method of a semiconductor apparatus further includes a step of diffusing the fluorine form the source area to a silicon oxide interface by heating at a temperature in a range from 600-1100° C. after the step of selectively implanting fluorine. Therefore, the dangling bond of the silicon oxide film interface is terminated, and it is possible to further effectively reduce the interface trap density of a semiconductor substrate.

### BRIEF DESCRIPTION OF THE DRAWINGS

FIG. 1 shows a production method of a semiconductor apparatus of a first embodiment, and the drawing is a cross-section of the semiconductor apparatus at a production step after device isolation.

FIG. 2 shows a production method of a semiconductor apparatus of a first embodiment, and the drawing is a cross-section of the semiconductor apparatus at a production step after forming a well layer and a channel doped layer.

FIG. 3 shows a production method of a semiconductor apparatus of a first embodiment, and the drawing is a cross-section of the semiconductor apparatus at a production step after forming films which constitute a gate electrode.

FIG. 4 shows a production method of a semiconductor apparatus of a first embodiment, and the drawing is a cross-section of the semiconductor apparatus at a production step after forming a gate electrode.

FIG. 5 shows a production method of a semiconductor apparatus of a first embodiment, and the drawing is a cross-section of the semiconductor apparatus at a production step after forming a source-drain area.

FIG. 6 shows a production method of a semiconductor apparatus of a first embodiment, and the drawing is a cross-section of the semiconductor apparatus at a production step of implanting fluorine only on a source area by using a photoresist film.

FIG. 7 shows a production method of a semiconductor apparatus of a first embodiment, and the drawing is a cross-section of the semiconductor apparatus at a production step after forming contact holes.

FIG. 8 shows a production method of a semiconductor apparatus of a first embodiment, and the drawing is a cross-section of the semiconductor apparatus at a production step after forming polycrystalline silicon plugs.

FIG. 9 shows a relationship between the refresh time and error bits of both a semiconductor apparatus of one embodiment below and a conventional example.

FIG. 10 shows a production method of a semiconductor apparatus of a second embodiment, and the drawing is a cross-section of the semiconductor apparatus at a production step after forming a well layer and a channel doped layer.

FIG. 11 shows a production method of a semiconductor apparatus of a second embodiment, and the drawing is a cross-section of the semiconductor apparatus at a production step after forming films which constitute a gate electrode.

FIG. 12 shows a production method of a semiconductor apparatus of a second embodiment, and the drawing is a cross-section of the semiconductor apparatus at a production step after forming a gate electrode.

FIG. 13 shows a production method of a semiconductor apparatus of a second embodiment, and the drawing is a cross-section of the semiconductor apparatus at a production step of implanting phosphorus.

FIG. 14 shows a production method of a semiconductor apparatus of a second embodiment, and the drawing is a cross-section of the semiconductor apparatus at a production step of implanting boron only on a source area by using a photoresist film.

FIG. 15 shows a production method of a semiconductor apparatus of a second embodiment, and the drawing is a cross-section of the semiconductor apparatus at a production step of implanting fluorine only on a source area by using a photoresist film.

FIG. 16 shows a production method of a semiconductor apparatus of a first embodiment, and the drawing is a cross-section of the semiconductor apparatus at a production step after forming a p-type pocket layer.

FIG. 17 shows a production method of a semiconductor apparatus of a second embodiment, and the drawing is a cross-section of the semiconductor apparatus at a production step after forming contact holes.

FIG. 18 shows a production method of a semiconductor apparatus of a second embodiment, and the drawing is a cross-section of the semiconductor apparatus at a production step after forming polycrystalline silicon plugs.

FIG. 19 shows a relationship between the amount of implanted fluorine and shift amount of a threshold voltage with regard to both a semiconductor apparatus of one embodiment below and a conventional example.

FIG. 20 shows a cross-section of the semiconductor apparatus of one embodiment.

### DETAILED DESCRIPTION OF THE INVENTION

### First Embodiment

Hereinafter, in reference to the drawings, a semiconductor apparatus of this embodiment of the present invention is explained in that the present invention is applied to a memory cell transistor of DRAM constituted as n-type MOS FET (Metal Oxide Semiconductor Field Effect Transistor). However, it should be noted that this embodiment is not a limitation for the present invention.

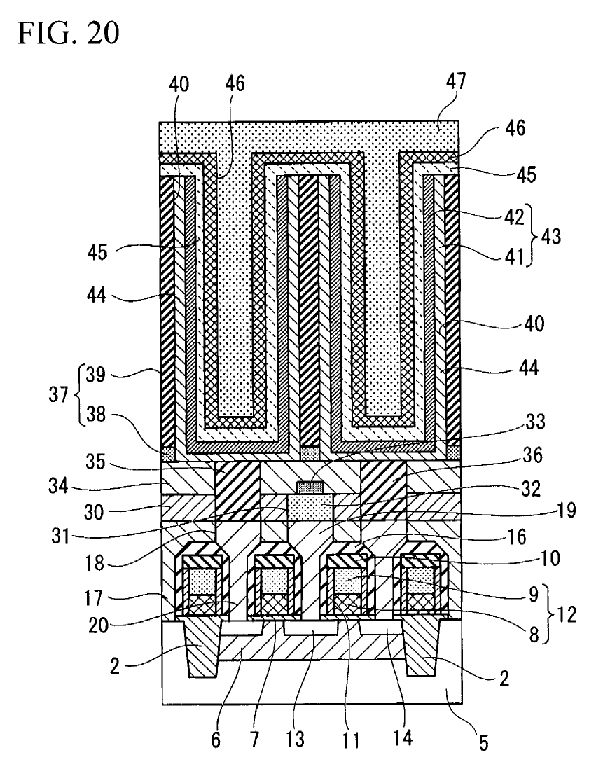

First, in reference to FIG. 20, the semiconductor apparatus, that is, an example of DRAM is explained to which a transistor shown in FIG. 8 is applied.

A semiconductor substrate 1 includes a semiconductor which is, for example, made from silicon. On the semiconductor substrate 1, a (p-type) well layer 5 is formed on a (deep n-well) well layer 3. In the drawings, a pair of insulation films (device isolation area) 2 is formed outside a portion of a transistor forming area of the semiconductor substrate 1 in order to insulate and isolate (device isolation) a transistor (selection transistor)

On the transistor forming area, the channel dope layer 6 is formed between the insulation films 2, and a gate insulation film 7 is formed so as to cover both the insulation films 2 and the channel dope layer 6.

Gate electrodes 12 are formed on the channel dope layer 6 so as to sandwich the gate insulation film 7. On the channel dope layer 6, a source area 13 and a drain area 14 are formed except for areas under the gate electrodes 12, and fluorine is implanted only on the source area 13.

The gate electrode 12 includes multiple layers which are a polysilicon film 8 and a tungsten silicide film (metallic film) 9. A doped polysilicone film formed by doping impurity upon forming the film in accordance with CVD method can be used as the polysilicon film 8, and tungsten (W) or other refractory metal can be used as the tungsten silicide film 9 in place to tungsten silicide (WSi).

A gate sidewall insulation film (sidewall) 11 is formed around the gate electrode 12 as sidewalls by using silicon oxide, silicon nitride, or the like. A first silicon nitride film 10 is formed on the gate electrode 12 and the gate sidewall insulation film 11. A second silicon nitride film 16 is formed on the insulation film 7 so as to cover both the gate sidewall insulation film 11 and the silicon nitride film 10. A second silicon oxide film 17 is formed on the second silicon nitride film 16.

A contact hole 18 is formed so as to touch an outside surface of the second silicon nitride film 16 which covers both the gate electrode 12 and the gate sidewall insulation film I1. A lower portion of the contact hole 18 pierces both the gate insulation film 7 and a surface of the second silicon nitride film 16 touching the gate insulation film 7 so as to touch the source area 13 or the drain area 14.

In a DRAM shown in FIG. 20 is an example of applying the present invention to a cell constitution in which 2 bits of memory cells are arranged in an active area surrounded by the insulation film 2.

In this embodiment, in one active area surrounded by the insulation film 2, an impurity diffused layers are provided at a center and both ends of the active area. In FIG. 20, the source area 13 is formed at a center portion, the drain diffused areas 14 are formed at right and left of the source area 13, and consequently, a fundamental constitution of a transistor is formed.

A first interlayer insulation film 30 is formed on overall the second silicon oxide film 17 and the polycrystalline silicon plug 19 and 20. The first interlayer insulation film 30 is made from a silicon oxide film.

A bit contact hole 31 pierces the first interlayer insulation film 30 in order to expose a surface of an edge of the polycrystalline silicon plug 19. A conductive material is filled in the bit contact hole 31 so as to form a bit contact plug 32.

On a surface of the bit contact plug 32, a bit wiring layer 33 is formed which is made from a metallic film such as a tungsten film. That is, the bit wiring layer 33 is connected to a diffused layer of the source electrode (source area 13) via the bit contact plug 32 and the polycrystalline silicon plug 19.

A second interlayer insulation film 34 is formed on overall the first interlayer insulation film 30 and the bit wiring layer 33. The second interlayer insulation film 34 is constituted from a silicon oxide film formed in accordance with a plasma CVD method.

A capacitor contact hole 35 pierces the second interlayer insulation film 34 and the first interlayer insulation film 30 so as to expose the surface of an edge of the polycrystalline silicon plug 20. A polycrystalline material which has a predetermined impurity concentration is filled in the capacitor contact hole 35 so as to form a capacitor contact plug 36.

On the second interlayer insulation film 34 and the capacitor contact plug 36, a third interlayer insulation film 37 is formed. The third interlayer insulation film 37 is constituted from a nitride film 38 and a third silicon oxide film 39 which is the core of a cylinder. The nitride film 38 is used as an etching stopper when a deep capacitor cylinder hole 40 (hereinafter, cylinder 40) is formed.

The cylinder (cylinder hole) 40 is formed which pierces the third interlayer insulation film 37 at a position where a surface of the capacitor contact plug 36 is exposed. On a bottom and around inside surface of the cylinder 40, a lower portion electrode 43 is formed in which a lower portion metallic electrode 42 is formed on an impurity included silicon film 41.

Near an interface between the impurity included silicon film 41 and the lower portion metallic electrode 42, the impurity included silicon film 41 obtains a silicide layer 44 which is formed by a chemical reaction between a metal of the lower portion metallic electrode 42 and silicon. The silicide layer 44 is a low resistance film and reduces an electric resistance between the capacitor and the capacitor contact plug 36.

On a surface of the lower portion electrode and on the interlayer insulation film 37, a capacitor insulation film 45 and an upper portion electrode 46 on the capacitor insulation film 45 form layers. In addition, a capacitor plate 47 is provided that fills a cylinder surrounded by the upper portion electrode 46 and that is formed as layers on the upper portion electrode 46 which is formed on the third interlayer insulation film 37. In other words, the lower portion electrode 43, the capacitor insulation film 45 and the capacitor plate 47 form a capacitor which is a capacitor memory portion for storing data.

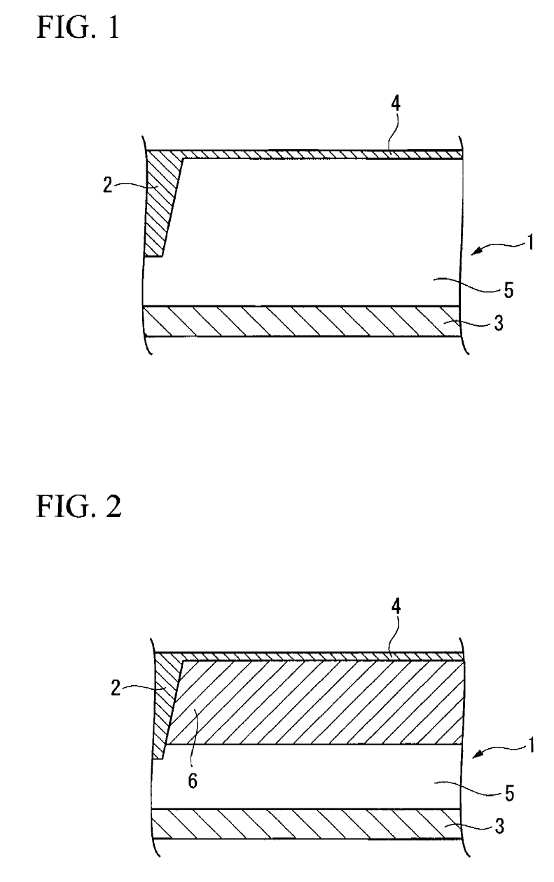

Hereinafter, a production method of the semiconductor apparatus is explained in reference to FIGS. 1-8 and 20.

First, as shown in FIG. 1, on a surface of the semiconductor substrate 1, a slit is formed, and the insulation film 2 is embedded in the slit in order to isolate (device isolation) the active area. A first silicon oxide film 4 of approximately 10 nm thickness is formed on a surface of the semiconductor substrate 1. The well layer 3 is formed in accordance with a deep n-well (buried n-type layer) by, for example, implanting a phosphorus dose amount of 1×10¹³/cm² via the first silicon oxide film 4 with an acceleration energy of 1500 keV. In the same manner, the p-type well layer 5 is formed by, for example, implanting a boron dose amount of 1×10¹³/cm² with an acceleration energy of 300 keV or dose amount of 1×10¹²/cm² with an acceleration energy of 100 keV.

As shown in FIG. 2, the (p-type) channel dope layer 6 is formed, for example, by a heating operation at 1000° C. for 10 seconds in a nitrogen atmosphere after implanting a boron dose amount of 1×10¹³/cm² with an acceleration energy of 15 keV.

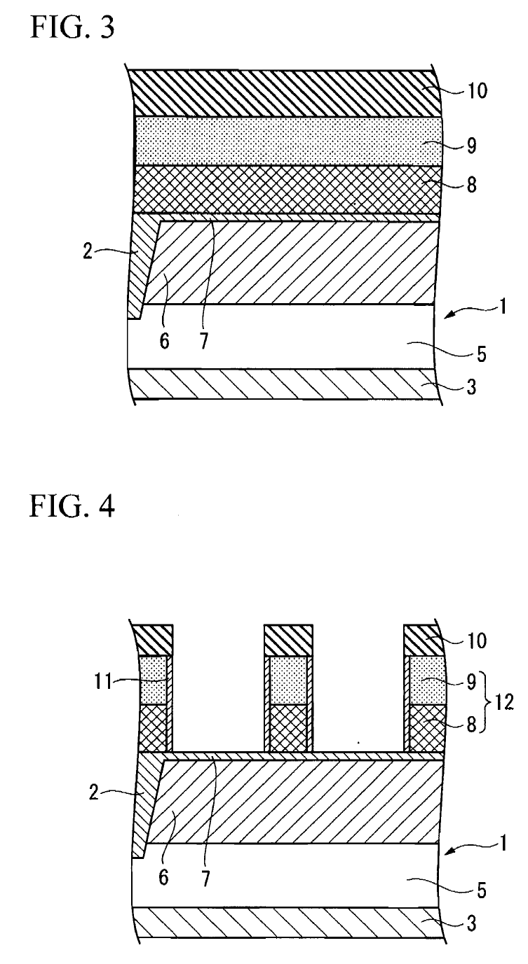

After removing the first silicon oxide film 4, as shown in FIG. 3, the gate insulation film 7 of approximately 7 nm thickness is formed on a silicon surface. On the gate insulation film 7, the polycrystalline silicon film 8 is formed which has thickness of approximately 100 nm and includes a high concentration of phosphorus, the tungsten silicide film 9 of approximately 100 nm in thickness is formed on the polycrystalline silicon film 8, and the first silicon nitride film 10 of approximately 100 nm in thickness is formed on the tungsten silicide film 9.

In this embodiment, the tungsten silicide film 9 is provided on the polycrystalline silicon film 8 in order to reduce the resistance of the gate electrode 12. However, it is possible to apply a polymetallic gate structure to the gate electrode 12 by using a refractory metal film such as tungsten (W) or titanium (Ti).

As shown in FIG. 4, a patterning operation of the first silicon nitride film 10, the tungsten silicide film 9 and the polycrystalline silicon film 8 is conducted in order to form the gate electrode 12 which is made from the polycrystalline silicon film 8 and the tungsten silicide film 9. The gate sidewall insulation film 11 of approximately 10 nm in thickness is formed on a side surface around the gate electrode 12 in accordance with a thermal oxidation method.

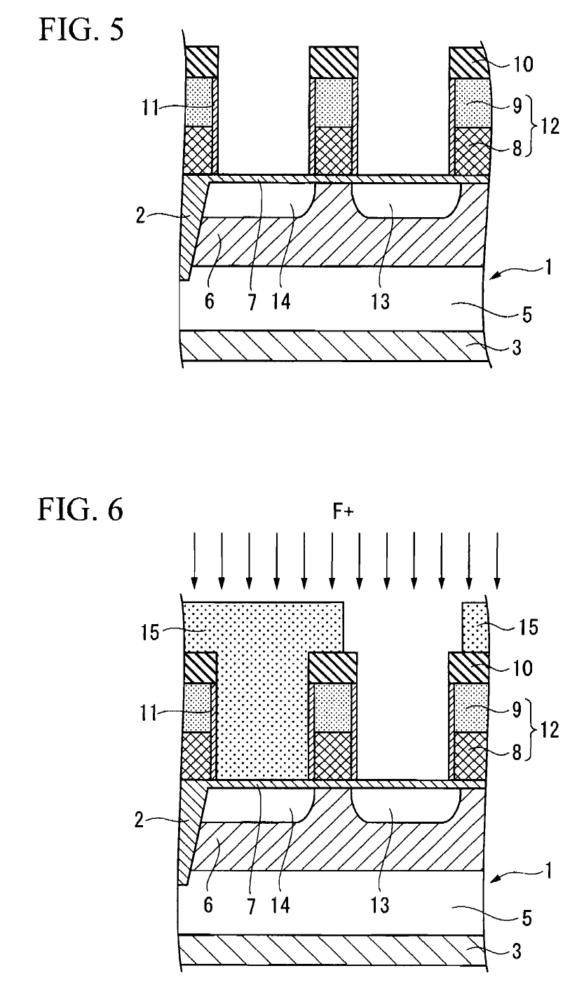

As shown in FIG. 5, the source area 13 and the drain area 14 of a source-drain diffused layer are formed, for example, by a heating operation at 950° C. for 10 seconds in a nitrogen atmosphere after implanting a phosphorus dose amount of 1×10³/cm² with an acceleration energy of 20 keV via an oxide film 7 by using the gate electrode 12 and the nitride film 10 as a mask.

In a later production step of wiring, the source area 13 is connected to a bit line, and the drain area 14 is connected to a capacitor.

DRAM maintains information as an electric charge. A state of maintaining an electric charge is, in other words, a transistor turned off while the drain area 14 is an n-type diffused layer which is connected to a capacitor. In such a case, in order to maintain the electric charge, it is necessary to reduce a connection leak current of the drain area 14 as much as possible. There are factors such as an electric field at drain junction, remained defects in a depletion layer and interface trap density of such a leak current.

As shown in FIG. 6, a mask which is a photoresist 15 is formed on the drain area 14 on a side of a capacitor, and fluorine of, for example, a dose amount of 1×10¹⁴/cm² is implanted with an acceleration energy of 10 keV only on the source area of the bit wiring.

It is possible to change the acceleration energy of implanted fluorine based on a constitution of the semiconductor apparatus, a thickness of a screen oxide (layer), and the like, if necessary. It is preferable to set a dose amount of fluorine in a range from 1×10¹⁴/cm² to 1×10¹⁶/cm².

If the dose amount is smaller than such a range, there is a possibility in which less fluorine is supplied to an interface of silicone, and consequently it is not possible to sufficiently terminate the dangling bond.

It is possible to terminate the dangling bond because the implanted fluorine on the diffused layer 13 is diffused on an interface of silicon, for example, by conducting a heating operation at 680° C. for 60 minutes.

A preferable temperature of such a heating operation after implanting fluorine is in a range from 600-800° C. It should be noted that it is possible to omit such a heating operation after implanting fluorine if the second silicon nitride film 16 is formed at a temperature of 600-800° C.

However, whether or not such a heating operation after implanting fluorine is conducted, it is preferable to implant fluorine in the source area 13 so as to include fluorine in a range from 1×10¹⁸/cm² to 1×10²²/cm².

In accordance with the above-described manner, the photoresist film 15 is formed on the drain area 14, and fluorine is selectively implanted in the source area 13. Therefore, it is possible to reduce the interface trap density without causing defects on the drain area 14 due to ion implantation. In addition, fluorine implanted in the source area 14 can be diffused both in silicon and on the interface, and consequently, it is possible to improve an effect of reducing the interface trap density.

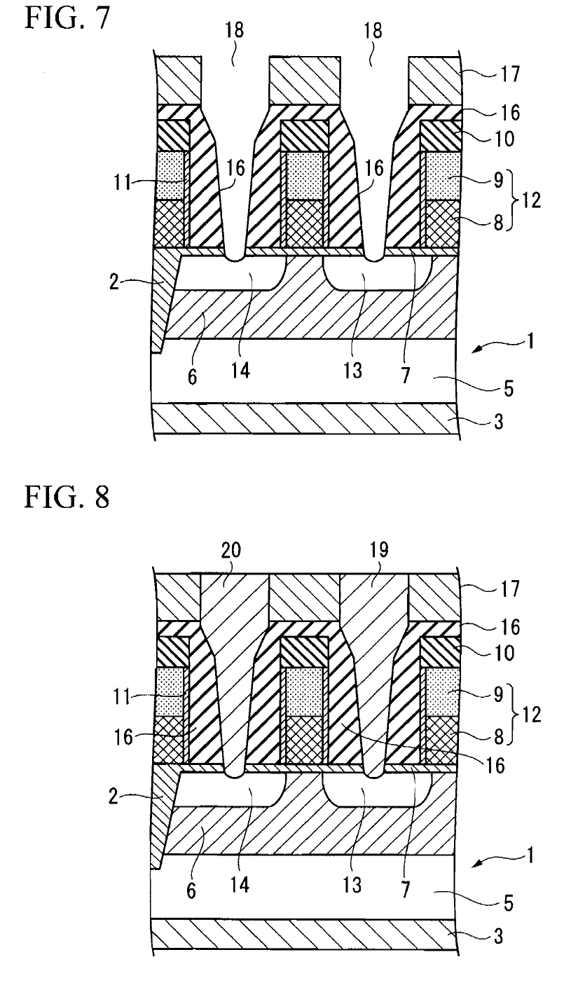

As shown in FIG. 7, the second silicon oxide film 17 of approximately 700 nm thickness is formed on the second silicon nitride film 16 of approximately 40 nm in thickness. The second silicon oxide film 17 is flattened in accordance with a generally-known CMP (chemical mechanical polishing) method, and the contact hole 18 is formed in accordance with SAC (self aligned contact) method.

As shown in FIG. 8, a layer of a polycrystalline silicon including phosphorus of high concentration is formed and is etched back in a generally-known method, and both the polycrystalline silicon plug (bit side) 19 and the polycrystalline silicon plug (capacitor side) 20 are formed. After this, through a wiring step, the polycrystalline silicon plug 19 is connected to a bit line, and the polycrystalline silicon plug 20 is connected to a capacitor. In addition, after forming word wirings and bit wirings and forming a capacitor constitution, a DRAM is formed.

Hereinafter, a production method of DRAM shown in FIG. 20 is explained.

On the overall surface of the second silicon oxide film 17 on which the polycrystalline silicon plugs 19 and 20 are formed, a first interlayer insulation film 30 made from silicon oxide film is formed so as to be approximately 200 nm.

After this, a gate contact hole (not shown in drawings) which pierces both the first interlayer insulation film 30 and the silicon oxide film 17 and which reaches the gate electrode 12 is formed by using a photoresist film as a mask in accordance with a dry etching technique. In the gate contact hole, a gate contact plug is formed in order to give an electric potential to the gate electrode 12. After this, the photo resist film is removed in accordance with a dry etching technique.

In addition, a bit contact hole 31 which pierces the first interlayer insulation film 30 and which reaches the cell contact plug is formed by using a photoresist film as a mask in accordance with a dry etching technique. After this, the photo resist film is removed in accordance with a dry etching technique.

It should be noted that in a gate contact forming step and a bit contact forming step, both the gate contact hole and the bit contact hole are formed at the same time at a peripheral circuit area which is not shown in drawings, the gate contact hole pierces both the first interlayer insulation film 30 and the silicon oxide film 17 and reaches the gate electrode of a transistor for peripheral circuits, and the bit contact hole pierces both the first interlayer insulation film 30 and the silicon oxide film 17 and reaches the diffused layer (source electrode and drain electrode).

In the bit contact hole 31, in the gate contact hole, and on the first interlayer insulation film 30, a film of titanium nitride (TiN) of approximately 13 nm is formed after forming a film of titanium (Ti) of approximately 11 nm, and both the films are barrier metal. After this, tungsten is filled in the bit contact hole 31 and forms a film of approximately 200 nm on the TiN film which has been formed on the first interlayer insulation film 30. In addition, in accordance with a CMP technique, Ti and TiN are removed except for Ti and TiN inside the bit contact hole 31 so as to form the bit contact plug 32.

On the first interlayer insulation film 30, on the bit contact plug 32 and on the gate contact plug, by applying a sputtering technique, a tungsten film of approximately 40 nm is formed after forming a tungsten nitride film of approximately 10 nm. A patterning operation is conducted on both the tungsten film and the tungsten nitride film by applying a photolithography technique and a dry etching technique in order to form a bit wiring layer 33 which is electrically connected to the bit contact plug 32. After this, by applying a CVD method, a silicon nitride film (not shown in drawings) of approximately 5 nm is formed as a protective oxide layer of the bit wiring layer 33.

On the first interlayer insulation film 30, on the bit contact plug 32 and on the bit wiring layer 33, by applying a plasma CVD technique, after forming a silicon oxide film of approximately 500 nm which is the second interlayer insulation film 34, the silicon oxide film is flattened by applying the CMP technique. After flattening the silicon oxide film, there is a gap of approximately 300 nm between a top surface of the second interlayer insulation film 34 and a top surface of the bit wiring layer 33.

On the second interlayer insulation film 34, by applying a photolithography technique and an etching technique, the capacitor contact hole 35 is formed which pierces both the second interlayer insulation film 34 and the first interlayer insulation film 30 and which reaches the polycrystalline silicon plug 20. In the capacitor contact hole 35, the capacitor contact plug 36 is formed which connects the polycrystalline silicon plug 20 and the cylinder 40.

A silicon film which is made from polycrystalline silicon, amorphous silicon, and/or the like obtained by doping impurity such as phosphorus, is filled in the capacitor contact hole 35 and forms a film of the second interlayer insulation film 34. After this, by a CMP technique and an etching back operation of chloride plasma gas using a dry etching technique, only the silicon film on the second interlayer insulation film is removed in order to form the capacitor contact plug 36.

It should be noted that, for example, it is possible to set concentration of impurities included in the silicon film from 1×10²⁰ to 4.5×10²⁰ atoms/cm³. When the silicon film is removed, a portion of the second interlayer insulation film 34 is shaved off.

Therefore, the distance between a top surface of the second interlayer insulation film 34 and a top surface of the bit wiring layer 33 is set to approximately 200 nm.

A nitride film 38 which is an etching stopper is formed on both the second interlayer insulation film 34 and the capacitor contact plug 36. A third silicon oxide film 39 of approximately 3 μm is formed on the nitride film 38 which is a core of a cylinder, and consequently, the third interlayer insulation film 37 is formed. By using a photolithography technique and an anisotropic etching technique, the cylinder 40 which pierces the third interlayer insulation film 37 and which reaches the capacitor contact plug 36 is formed.

In order to reduce the resistance of an interface of the capacitor contact plug 36 before forming a silicon film including impurity 41 at a next step, a wet pretreatment is conducted by using a solution including hydrofluoric acid, and a natural oxide generated on a surface of the silicon film inside the capacitor contact hole 35 is removed.

After conducting the pretreatment, by using a CVD method, on a bottom face and side surface inside each of the cylinders 40 and on a top surface of a partition wall between the cylinders 40, the silicon film including impurity 41 of approximately 25-35 nm is formed which is made from polycrystalline silicon, amorphous silicon, and/or the like obtained by doping impurity. It should be noted that the concentration of impurities included in the silicon film including impurity 41 is approximately 4.4×10²⁰ atoms/cm³.

A positive photoresist is painted on the whole surface of the silicon film including impurity 41, the whole surface is exposed, and a development operation is conducted. As a result, only an inside portion of the cylinder 40 is not exposed, and the photoresist is remained. The remained photoresist is used as a protective film for protecting the silicon film including impurity 41 inside the cylinder 40, a portion of the impurity included film 41 formed on the partition wall between the cylinders 40 is etched back by applying Cl in accordance with an isotropic etching technique. Therefore, the silicon film including impurity 41 remains only in the cylinder 40. In addition, the photoresist is removed by applying both a dry etching technique (removing by using plasma) and a wet strip.

In a following step, the lower portion metallic electrode 42 of a MIM (metal-insulator-metal) structure is formed.

The lower portion metallic electrode 42 can be provided, for example, as multiple layers obtained by forming a TiN film on a Ti film that are formed in accordance with a high-temperature plasma CVD technique and a thermal CVD technique. Here, the Ti film is approximately 10 nm in thickness and the TiN film is approximately 20 nm in thickness. If the Ti film is formed at a high temperature such as approximately 650° C., the Ti film is fully silicided in situ, and consequently, a film with a low resistance which is called silicide (TiSi₂) is formed at an interface between the third silicon oxide film 39 and the lower portion metallic electrode 42. In this production method, because the silicon film including impurity 41 is formed on both a bottom face and a side surface inside the cylinders 40, an area at which the silicon film touches Ti is large, and consequently, the silicide layer 44 is formed on a large area even though the state of Ti which is covering is not satisfactory. Therefore, it is possible to avoid a forming error of the silicide layer 44, and it is possible to reduce the resistance between the capacitor and the capacitor contact plug 36. It should be noted that a metallic material, the film thickness and the forming method of the lower portion metallic electrode 42 are not limited by the above description

It should be noted that in order to obtain a preferable contacting condition, for example, it is preferable to set the film thickness of the third silicon oxide film 39 at a range of approximately 20-40 nm, and it is preferable to set the thickness of the Ti film at a range of approximately 10-15 nm.

If the thickness of the third silicon oxide film 39 exceeds the above-described range by a large amount, it is not appropriate for a capacitor due to a reduced capacitance even though it is fully possible to form the silicide layer. If the thickness of the third silicon film 39 is thinner than 15 nm, the contacting condition is deteriorated due to a lack of thickness of the formed silicide layer 44. With regard to the Ti film of the lower portion metallic electrode 42, if the thickness exceeds 20 nm, there is an unpleasant problem because of an excess reaction of the silicide layer. In addition, if the thickness is thinner than 5 nm, a resistance increases between the capacitor and the capacitor contact plug 36 due to a lack of formed silicide layer 44.

After forming the lower portion electrode 43, a metallic film (a lower portion metallic electrode 42) of a partition wall of the cylinder 40 is removed in the same manner as the third silicon oxide film 39. As a concrete example, a positive photoresist is painted on a whole surface again, the whole surface is exposed, and a development operation is conducted. Therefore, only an inside portion of the cylinder 40 is not exposed, and the photoresist remains. The remaining photoresist is used as a protective film for protecting the lower portion metallic electrode 42 inside the cylinder 40, a portion of the lower portion metallic electrode 42 formed on the partition wall between the cylinders 40 is etched back by applying Cl in accordance with an isotropic etching technique. Therefore, the lower portion metallic electrode 42 remains only in the cylinder 40. In addition, the photoresist is removed by applying both a dry etching technique (removing by using plasma) and a wet pretreatment.

It should be noted that the lower portion electrode 43 includes both the silicon film including impurity 41 and the lower portion metallic electrode 42.

After forming a film with a high dielectric constant of a few nm thickness made from such as Al₂O₃ and/or HfO₂, that is, the capacitor insulation film 45 on the lower portion electrode 43 inside the cylinder 40, TiN is formed as the upper portion electrode 46 on the capacitor insulation film 45, and W (tungsten) is formed as the capacitor plate 47 on the upper portion electrode 46. In accordance with such a production step, the semiconductor memory apparatus is produced which has a cylinder structure in which the third silicon oxide film 39 is provided under a MIM structure. It should be noted that it is possible to apply other oxide films to the capacitor insulation film 45 such as Ta₂O₅ and a film including multiple layers of oxide films.

It should be noted that in the above-described embodiment, materials which constitute portions of the semiconductor memory apparatus, the thickness of films, the method for forming the films, and the like are examples and can be appropriately modified.

As described above, fluorine is implanted in only the source area 13, and it is possible to avoid defects on the drain area 14 caused by ion implantation and to reduce the interface trap density by fluorine introduced into the interface of silicon. Therefore, if the above-described embodiment is applied to a memory cell transistor of DRAM, it is possible to reduce leak current and to improve refresh characteristics.

The above-described embodiment is an example of a memory cell transistor of DRAM. However, it is possible to apply the embodiment to a generally used n-type MOS FET and p-type MOS FET in the similar manner. In addition, in order to reduce electric field of a drain, it is possible to apply a generally known technique in which a pocket implantation is conducted on only the source, and it is possible to further effectively reduce leak current.

Such a method is explained as a second embodiment in reference to the drawings.

### Second Embodiment

Hereinafter, in reference to the drawings, a semiconductor memory apparatus of a second embodiment is explained which is an example of applying the second embodiment to a memory cell transistor which has a n-type MOS FET structure produced by conducting a pocket implantation of fluorine only to the source. However, it should be noted that the second embodiment does not limit a scope of the present invention.

First an example is explained in which a DRAM as shown in FIG. 20 is constituted by applying a transistor shown in FIG. 18.

In the same manner as shown in the first embodiment, a semiconductor substrate 1 is formed by applying a semiconductor such as silicon including impurities of a predetermined concentration. On the semiconductor substrate 1, a (p-type) well layer is formed on a (deep n-well) well layer 3. In the drawings, a pair of insulation films (device isolation area) 2 is formed outside a portion of a transistor forming area of the semiconductor substrate 1 in order to insulate and isolate (device isolation) a transistor (selection transistor)

On the transistor forming area, the channel dope layer 6 is formed between the insulation films 2, and a gate insulation film 7 is formed so as to cover both the insulation films 2 and the channel dope layer 6.

Gate electrodes 12 are formed on the channel dope layer 6 so as to sandwich the gate insulation film 7. On the channel dope layer 6, a source area and a drain area 14 and the source area 13 are formed by implanting phosphorus.

In addition, boron and fluorine are implanted only on the source area 13, and a p-type pocket layer 23 is formed at a boundary between the source area 13 and the channel dope layer 6.

The gate electrode 12 includes multiple layers which are a polysilicon film 8 and a tungsten silicide film (metallic film) 9. A doped polysilicone film formed by doping impurity upon forming the film in accordance with CVD method can be used as the polysilicon film 8, and tungsten (W) or other refractory metal can be used as the tungsten silicide film 9 in place to tungsten silicide (WSi).

A gate sidewall insulation film (sidewall) 11 is formed around the gate electrode 12 as sidewalls by using silicon oxide, silicon nitride, or the like. A second silicon nitride film 16 is formed on the insulation film 7 so as to cover the gate electrode 12. A second silicon oxide film 17 is formed on the second silicon nitride film 16.

A contact hole 18 is formed so as to touch an outside surface of the second silicon nitride film 16 which covers both the gate electrode 12 and the gate sidewall insulation film 11. A lower portion of the contact hole 18 pierces both the gate insulation film 7 and a surface of the second silicon nitride film 16, touching the gate insulation film 7 so as to touch the source area 13 or the drain area 14, and a fundamental structure of a transistor is constituted.

A constitution of DRAM applying such a transistor is the same as the first embodiment.

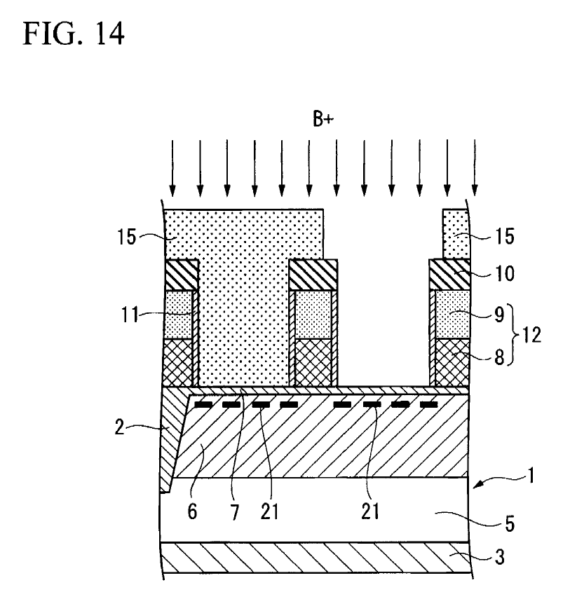

Hereinafter, a production method of such a semiconductor apparatus is explained in reference to FIGS. 10-18.

First, in the same manner as described in the first embodiment, a device isolation operation is conducted, and well layers 3 and 5 are formed on the semiconductor substrate 1.

The (p-type) channel dope layer 6 is formed as shown in FIG. 10, for example, by a heating operation at 1000° C. for 10 seconds in a nitrogen atmosphere after implanting a boron dose amount of 7×10¹²/cm² with acceleration energy of 15 keV.

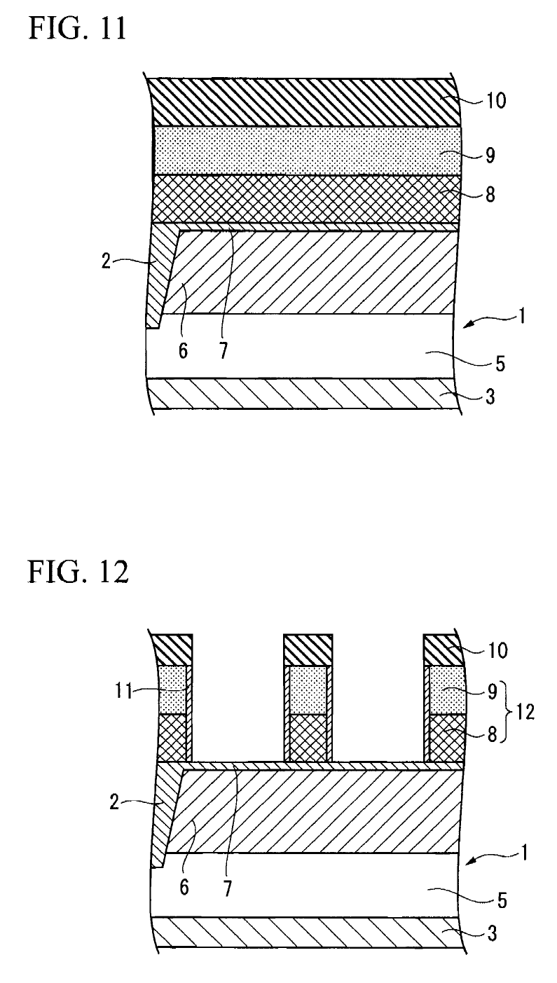

After removing the first silicon oxide film 4, as shown in FIG. 11, the gate insulation film 7 of approximately 7 nm in thickness is formed on a silicon surface. On the gate insulation film 7, the polycrystalline silicon film 8 is formed which is approximately 100 nm in thickness and includes phosphorus of high concentration, the tungsten silicide film 9 of approximately 100 nm thickness is formed on the polycrystalline silicon film 8, and the first silicon nitride film 10 of approximately 100 nm in thickness is formed on the tungsten silicide film 9.

As shown in FIG. 12, a patterning operation of the first silicon nitride film 10, the tungsten silicide film 9 and the polycrystalline silicon film 8 is conducted in order to form the gate electrode 12 which is made from the polycrystalline silicon film 8 and the tungsten silicide film 9. The gate sidewall insulation film 11 of approximately 10 nm thickness is formed on a side surface around the gate electrode 12 in accordance with a thermal oxidation method.

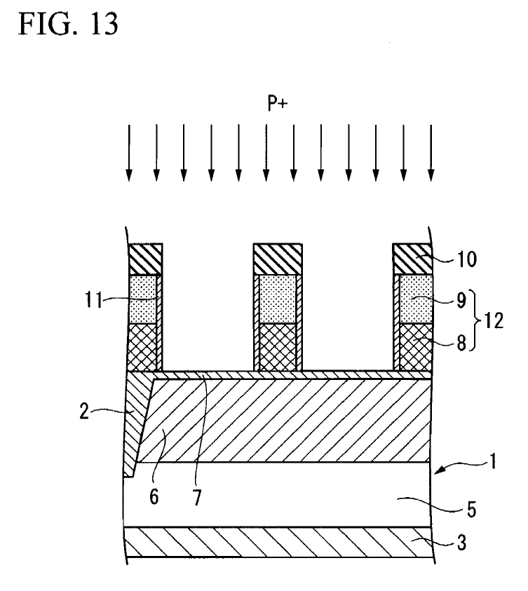

As shown in FIG. 13, for example, a phosphorus dose amount of 1×10¹³/cm² with an acceleration energy of 20 keV is implanted via an oxide film 7 by using the gate electrode 12 and the nitride film 10 as a mask.

As shown in FIG. 6, a mask which is a photoresist 15 is formed on the drain area 14 on a side of a capacitor, and boron of, for example, dose amount of 1×10¹³/cm² is implanted with an acceleration energy of 10 keV only on the source area of the bit wiring.

As shown in FIG. 15, after implanting fluorine of a dose amount of 1×10¹⁵/cm² is implanted with an acceleration energy of 10 keV, a mask of the photoresist 15 is removed.

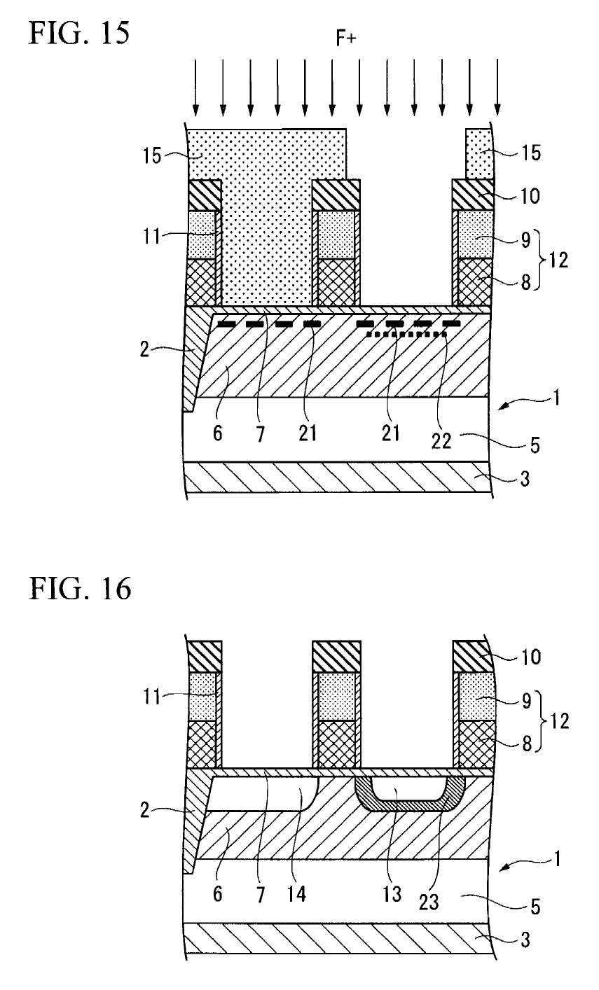

As shown in FIG. 16, in order to activate the implanted impurity, a heating operation at 900-1100° C. for several seconds in a nitrogen or oxide atmosphere, preferably at 900° C. for ten seconds in a nitrogen atmosphere, is conducted, and the source area 13, the drain area 14 and the p-type pocket layer 23 are formed.

It should be noted that if such a heating operation is conducted which is appropriate for an activation of impurity, an out diffusion of fluorine is caused, and the amount of fluorine is reduced which affects a termination of the interface trap density. Therefore, in this embodiment, more fluorine is implanted than the first embodiment. A dose amount of fluorine is preferably in a range from 1×10¹⁵/cm² to 1×10¹⁶/cm².

The p-type pocket layer 23 increases the threshold voltage of the memory cell transistor, and it is possible to reduce a leak current of the drain area 14 of the capacitor by applying a lower concentration of impurity of the (p-type) channel dope layer 6 compared to the first embodiment. Here, the thermal diffusion of boron is decreased due to implantation of fluorine, and the concentration of boron of the (p-type) pocket layer 23 is maintained at a high concentration. Therefore, the threshold voltage of a memory cell transistor is increased.

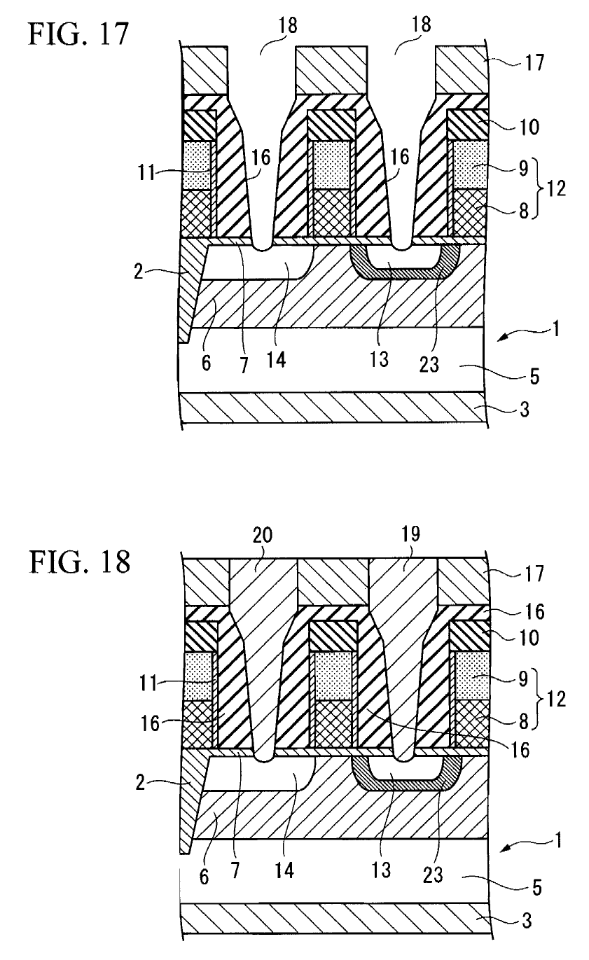

As shown in FIG. 17, the second silicon oxide film 17 of approximately 700 nm in thickness is formed on the second silicon nitride film 16 of approximately 40 nm thickness. The second silicon oxide film 17 is flattened in accordance with a generally-known CMP (chemical mechanical polishing) method, and the contact hole 18 is formed in accordance with the SAC (self aligned contact) method.

As shown in FIG. 18, a layer of a polycrystalline silicon including phosphorus of high concentration is formed and is etched back in a generally-known method, and both the polycrystalline silicon plug 19 and 20 are formed.

After this, through a wiring step, the polycrystalline silicon plug 19 is connected to a bit line, and the polycrystalline silicon plug 20 is connected to a capacitor (not shown in the drawings). A production method of DRAM to which the above-described transistor is the same as the first embodiment.

As described above, pocket implantation of fluorine is conducted on only the source area 13, and it is possible to effectively avoid defects on the drain area 14 caused by ion implantation and to reduce interface trap density by fluorine introduced into the interface of silicon. Therefore, if the above-described embodiment is applied to a memory cell transistor of DRAM, it is possible to further reduce a leak current and to further improve refresh characteristics.

### EXAMPLES

### First Example and First Comparative Example

A memory cell transistor of DRAM (Example 1) which has a constitution of n-type MOS FET (Metal Oxide Semiconductor Field Effect Transistor) shown in FIGS. 1-8 and a Comparative Example 1 were produced, and DRAM apparatuses as shown in FIG. 20 were produced.

First, as shown in FIG. 1, on a surface of the semiconductor substrate 1, a slit was formed, and the insulation film 2 was embedded in the slit in order to isolate (device isolation) the active area. A first silicon oxide film 4 of approximately 10 nm in thickness was formed on a surface of the semiconductor substrate 1. The well layer 3 was formed in accordance with a deep n-well by implanting a phosphorus a dose amount of 1×10¹³/cm² via the first silicon oxide film 4 with an acceleration energy of 1500 keV. In the same manner, the p-type well layer 5 was formed by implanting a boron dose amount of 1×10¹³/cm² with an acceleration energy of 300 keV or a dose amount of 1×10¹²/cm² with an acceleration energy of 100 keV.

As shown in FIG. 2, the (p-type) channel dope layer 6 was formed by a heating operation at 1000° C. for 10 seconds in nitrogen atmosphere after implanting a boron dose amount of 1×10¹³/cm² with acceleration energy of 15 keV.

After removing the first silicon oxide film 4, as shown in FIG. 3, the gate insulation film 7 of 7 nm in thickness was formed on a silicon surface. On the gate insulation film 7, the polycrystalline silicon film 8 was formed which is 100 nm in thickness and includes phosphorus of a high concentration, the tungsten silicide film 9 of 100 nm in thickness was formed on the polycrystalline silicon film 8, and the first silicon nitride film 10 of 100 nm in thickness was formed on the tungsten silicide film 9.

As shown in FIG. 4, a patterning operation of the first silicon nitride film 10, the tungsten silicide film 9 and the polycrystalline silicon film 8 was conducted in order to form the gate electrode 12 which is made from the polycrystalline silicon film 8 and the tungsten silicide film 9. The gate sidewall insulation film 11 of 10 nm in thickness was formed on a side surface around the gate electrode 12 in accordance with a thermal oxidation method.

As shown in FIG. 5, the source area 13 and the drain area 14 of a source-drain diffused layer were formed by a heating operation at 950° C. for 10 seconds in a nitrogen atmosphere after implanting a phosphorus a dose amount of 1×10¹³/cm² with an acceleration energy of 20 keV via an oxide film 7 by using the gate electrode 12 and the nitride film 10 as a mask.

As shown in FIG. 6, a mask which is a photoresist 15 was formed on the drain area 14 on a side of a capacitor, and fluorine of dose amount of 1×10¹⁴/cm² was implanted with an acceleration energy of 10 keV so as to provide fluorine of 2×10¹⁹/cm³ only on the source area of the bit wiring.

The implanted fluorine on the diffused layer (source area) 13 was diffused on an interface of silicon by conducting a heating operation at 680° C. for 60 minutes.

As shown in FIG. 7, the second silicon oxide film 17 of 700 nm in thickness was formed on the second silicon nitride film 16 of 40 nm in thickness. The second silicon oxide film 17 was flattened in accordance with a generally-known CMP (chemical mechanical polishing) method, and the contact hole 18 was formed in accordance with the SAC (self aligned contact) method.

As shown in FIG. 8, a layer of a polycrystalline silicon including phosphorus of a high concentration was formed and was etched back in a generally-known method, and both the polycrystalline silicon plug (bit side) 19 and the polycrystalline silicon plug (capacitor side) 20 were formed. After this, through a wiring step, the polycrystalline silicon plug 19 was connected to a bit line, and the polycrystalline silicon plug 20 was connected to a capacitor. In addition, after forming word wirings and bit wirings and forming a capacitor constitution, a DRAM as shown in FIG. 20 was formed.

In addition, the Comparative Example 1 was produced which has almost the same constitution of a transistor as the Example 1, but fluorine was not implanted in the Comparative Example 1.

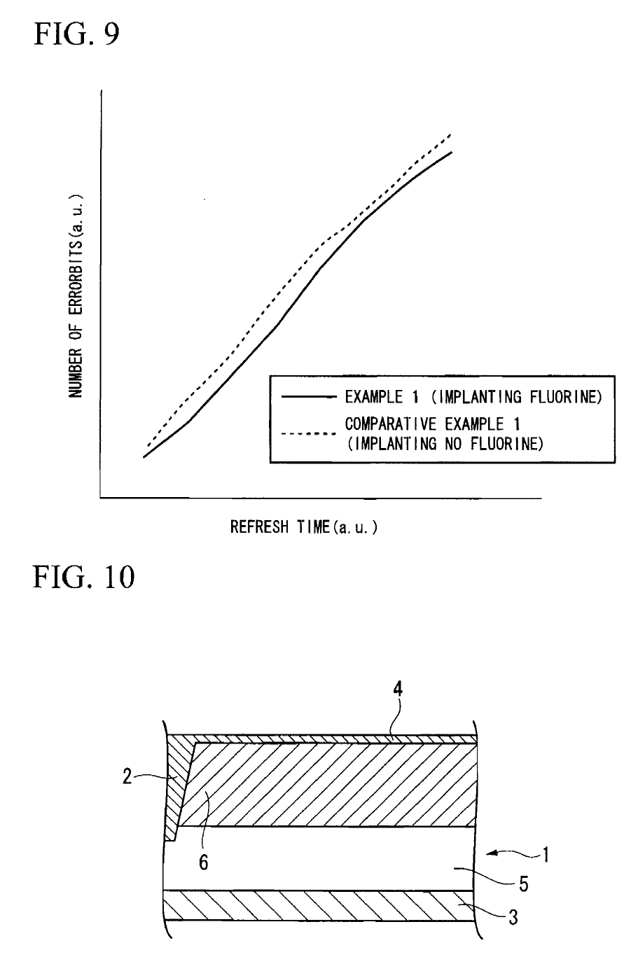

With regard to the Example 1 and Comparative Example 1, a refresh time and number of error bits were measured in a test of writing “1” on all bits of a DRAM memory cell of 512 M bits. The measurement results are shown in FIG. 9 (“a.u.” means “arbitrary unit”).

It was recognized that it is possible to reduce error bits and improve refresh characteristics in the Example 1 in which the present invention was applied and fluorine was implanted compared to the Comparative Example 1 in which fluorine was not implanted.

### Examples 2, 3 and Comparative Example 2

Memory cell transistors of DRAM (Examples 2 and 3) which have constitutions of n-type MOS FET (Metal Oxide Semiconductor Field Effect Transistor) shown in FIGS. 10-18 and a Comparative Example 2 were produced, and DRAM apparatuses as shown in FIG. 20 were produced.

In the same manner as the Example 1, a device isolation operation was conducted, and well layers 3 and 5 were formed on the semiconductor substrate 1. As shown in FIG. 10, the (p-type) channel dope layer 6 was formed by a heating operation at 1000° C. for 10 seconds in nitrogen atmosphere after implanting a boron dose amount of 1×10¹²/cm² with acceleration energy of 15 keV.

After removing the first silicon oxide film 4, as shown in FIG. 1, the gate insulation film 7 of 7 nm in thickness was formed on a silicon surface. On the gate insulation film 7, the polycrystalline silicon film 8 was formed which is 100 nm in thickness and includes phosphorus of a high concentration, the tungsten silicide film 9 of 100 nm in thickness was formed on the polycrystalline silicon film 8, and the first silicon nitride film 10 of 100 nm in thickness was formed on the tungsten silicide film 9.

As shown in FIG. 12, a patterning operation of the first silicon nitride film 10, the tungsten silicide film 9 and the polycrystalline silicon film 8 was conducted in order to form the gate electrode 12 which is made from the polycrystalline silicon film 8 and the tungsten silicide film 9. The gate sidewall insulation film 11 of 10 nm in thickness was formed on a side surface around the gate electrode 12 in accordance with a thermal oxidation method.

As shown in FIG. 13, a phosphorus a dose amount of 1×10¹³/cm² with acceleration energy of 20 keV was implanted via an oxide film 7 by using the gate electrode 12 and the nitride film 10 as a mask.

As shown in FIG. 6, a mask which is a photoresist 15 was formed on the drain area 14 on a side of a capacitor, and boron of a dose amount of 1×10¹³/cm² was implanted with an acceleration energy of 10 keV only on the source area of the bit wiring.

As shown in FIG. 15, fluorine was implanted with an acceleration energy of 10 keV only on the source area 13.

After implanting fluorine, a mask of the photoresist 15 was removed, and a heating operation at 900-100° C. for 10 seconds was conducted in a nitrogen atmosphere.

The Comparative Example 2 has almost the same constitution of a transistor as the Examples 2 and 3, but fluorine was not implanted.

As shown in FIG. 16, in order to activate the implanted impurity, a heating operation was conducted at 900° C. for 10 seconds in a nitrogen atmosphere, and the source area 13, the drain area 14 and the p-type pocket layer 23 were formed.

As shown in FIG. 17, the second silicon oxide film 17 of 700 nm in thickness was formed on the second silicon nitride film 16 of 40 nm in thickness. The second silicon oxide film 17 was flattened in accordance with a generally-known CMP (chemical mechanical polishing) method, and the contact hole 18 was formed in accordance with SAC (self aligned contact) method.

As shown in FIG. 18, a layer of a polycrystalline silicon including phosphorus of a high concentration was formed and was etched back in a generally-known method, and both the polycrystalline silicon plug 19 and 20 were formed.

After this, through a wiring step, the polycrystalline silicon plug 19 was connected to a bit line, the polycrystalline silicon plug 20 was connected to a capacitor, and DRAM shown in FIG. 20 was produced.

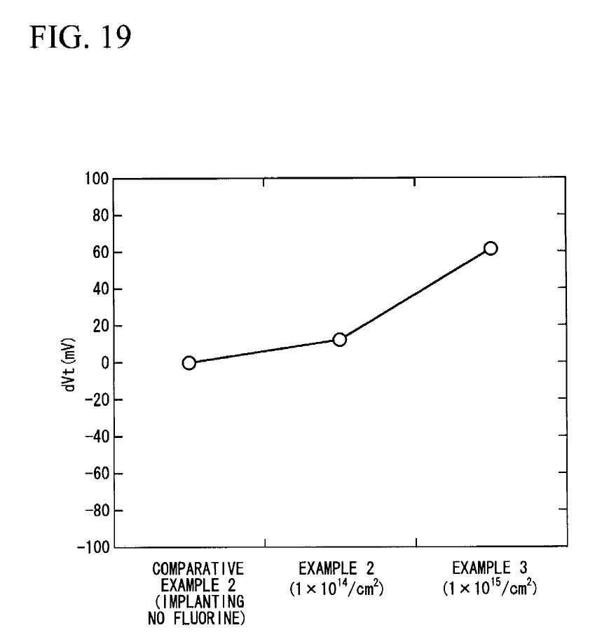

With regard to the Examples 2, 3 and the Comparative Example 2, a shift amount of a threshold voltage was measured while implanting a fixed amount of impurities, and the measurement results are shown in FIG. 19. Values in parenthesis are dose amounts of implanted fluorine. A shift amount of a threshold voltage of the Example 3 is larger than the Example 2, and both of the Examples 2 and 3 have larger shift amounts than the Comparative Example 2.

If a concentration of boron of the p-type channel dope layer 6 is lowered in order to obtain the same threshold voltage as a case of implanting no fluorine, an electric field of source/drain connection on a side of the capacitor, and it is possible to further reduce a connection leak current.

As shown in the above-described results, it is possible to eliminate defects of ion implantation on the drain area 14 because fluorine is implanted only on the source area 13, and the interface trap density is reduced by fluorine introduced in a silicon interface. Therefore, it is possible to reduce a leak current and improve refresh characteristics if the present invention is applied to a memory cell transistor of DRAM. In addition, it is possible to improve such advantages if applying a pocket implantation of larger dose amount of fluorine.

A memory cell transistor of DRAM which is applied to information equipments that require low power consumption is one example for applying the present invention.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A semiconductor apparatus comprising:
a semiconductor substrate;
a well layer formed on the semiconductor substrate;
a channel dope layer formed on the well layer;
a source/drain diffused layer provided at an upper peripheral of the channel dope layer;
gate electrodes formed on the channel dope layer via a gate insulation film;
a polycrystalline silicon plug which is formed between the gate electrodes and which touches the source/drain diffused layer while piercing the gate insulation film; and
fluorine which is selectively implanted only in a source area of the source/drain diffused layer.

2. A semiconductor apparatus according to claim 1, wherein the fluorine is included in the source layer at a range from 1×10¹⁸/cm³ to 1×10²²/cm³.

3. A semiconductor apparatus according to claim 1, wherein a dose amount of the fluorine is in a range from 1×10¹⁴/cm² to 1×10¹⁷/cm².

4. A semiconductor apparatus according to claim 1, wherein a dose amount of the fluorine is in a range from 1×10¹⁵/cm² to 1×10¹⁶/cm².

5. A semiconductor apparatus according to claim 1, wherein the fluorine is diffused from the source area to a silicon oxide film interface by conducting a heating operation after implanting the fluorine.

6. A production method of a semiconductor apparatus comprising the steps of:
forming a well layer on a semiconductor substrate;
forming a channel dope layer on the well layer;
forming a source/drain diffused layer at an upper peripheral of the channel dope layer;
forming gate electrodes on the channel dope layer via a gate insulation film;
forming a polycrystalline silicon plug which touches the source/drain diffused layer while piercing the gate insulation film, between the gate electrodes; and
selectively implanting fluorine only in a source area of the source/drain diffused layer.

7. A production method of a semiconductor apparatus according to claim 6, wherein the fluorine is selectively implanted only in the source area by using a photoresist mask.

8. A production method of a semiconductor apparatus according to claim 6, wherein the fluorine is included in the source layer at a range from 1×10¹⁸/cm³ to 1×10²²/cm³ at the step of selectively implanting fluorine.

9. A production method of a semiconductor apparatus according to claim 6, wherein a dose amount of the fluorine is in a range from 1×10¹⁴/cm² to 1×10¹⁷/cm² at the step of selectively implanting fluorine.

10. A production method of a semiconductor apparatus according to claim 6, wherein a dose amount of the fluorine is in a range from 1×10¹⁵/cm² to 1×10¹⁶/cm² at the step of selectively implanting fluorine.

11. A production method of a semiconductor apparatus according to claim 6, wherein the fluorine is implanted with an acceleration energy of 0.5-50 keV at the step of selectively implanting fluorine.

12. A production method of a semiconductor apparatus according to claim 6 further comprising a step of diffusing the fluorine form the source area to a silicon oxide film interface by heating at a temperature in a range from 600-1100° C. after the step of selectively implanting fluorine.
